(19) United States
(12) Patent Application Publication
(10) Pub. No.: US 2009/0116379 A1
(43) Pub. Date: May 7, 2009

(54) Insufficient bandwidth notification for transmission of multimedia program

(75) Inventor: Moshiur Rahman, Marlboro, NJ (US)

Correspondence Address: AT&T Legal Department - LNAP;Attn: Patent Docketing, Room 2A- 207, One AT & T Way, Bedminster, NJ, 07921, US

(73) Assignee: AT&T Knowledge Ventures, LP, Reno, NV (US)

(21) Appl. No.: 11/934,596

(22) Filed: Nov. 2, 2007

(51) Int. Cl. G01R 31/08; H04N 7/173

(52) U.S. Cl. 370/229; 725/87

(57) ABSTRACT

A network connection is established between a multimedia viewer at a viewer's premises and a service provider. The viewer requests presentation of a multimedia channel via the multimedia viewer. In response to the request, an available bandwidth of the network connection is determined, as is a bandwidth requirement of the requested multimedia channel. In response to determining the bandwidth requirement is inconsistent with the available bandwidth, the viewer is provided with an indicator that the first multimedia channel is unavailable for presentation by the multimedia receiver. In response to determining the bandwidth requirement is consistent with the available bandwidth, data representing the content of the requested multimedia channel is transmitted to the multimedia receiver for presentation to the viewer.

### FIELD OF THE DISCLOSURE

The present disclosure generally relates to the provision of multimedia content, and more particularly relates to the provision of multimedia content via a network.

### BACKGROUND

Service providers, such as cable television providers and satellite television providers, typically make a number of multimedia channels available to viewers. In analog implementations, the multimedia channels are multiplexed into the same signal, so a display device can access a particular channel by tuning its receiver to a particular frequency associated with the channel. In digital implementations, however, a limited number of channels specifically requested by the viewer are transmitted to the display device due to bandwidth limitations of the network connection. In certain instances, a viewer may request a particular channel but the network connection providing the multimedia content may not have sufficient bandwidth to reliably transmit the requested channel. To illustrate, the service provider may be transmitting other multimedia channels to the viewer's premises via the network connection at the time the channel was selected or the viewer may have selected, for example, a high-definition television (HDTV) channel but the network connection is capable of supporting data rates commensurate with only standard definition (SD) channels. In such instances, the viewer typically is presented with only a blank screen, thereby leaving the viewer to question whether there is a problem with the operation of the display device or with the service provider.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a diagram illustrating an example multimedia content distribution system in accordance with at least one embodiment of the present disclosure;

FIG. 2 is a flow diagram illustrating an example method for notifying a viewer of insufficient bandwidth for the provision of a requested multimedia channel in accordance with at least one embodiment of the present disclosure;

FIG. 3 is flow diagram illustrating an example method for notifying a viewer of insufficient bandwidth for the provision of a requested multimedia channel and providing to the viewer an option to terminate provision of another multimedia channel so as to increase available bandwidth for the requested multimedia channel in accordance with at least one embodiment of the present disclosure;

FIG. 4 is a diagram illustrating a display of a visual indicator of insufficient bandwidth for the provision of a multimedia channel requested by a viewer in accordance with at least one embodiment of the present disclosure;

FIG. 5 is a diagram illustrating a display of a visual indicator of insufficient bandwidth for the provision of a multimedia channel requested by a viewer and a listing of other multimedia channels available for termination by the viewer so as to increase available bandwidth in accordance with at least one embodiment of the present disclosure;

FIG. 6 is a diagram illustrating a particular digital subscriber line (DSL)-based implementation of the multimedia content distribution system of FIG. 1 in accordance with at least one embodiment of the present disclosure;

FIG. 7 is a flow diagram illustrating an example method for notifying a viewer of insufficient bandwidth for a selected multimedia channel in the context of the implementation of FIG. 6 in accordance with at least one embodiment of the present disclosure;

FIG. 8 is a block diagram illustrating an example Internet Protocol Television (IPTV) network in which the multimedia content distribution system of FIG. 1 can be implemented in accordance with at least one embodiment of the present disclosure; and

FIG. 9 is a diagram illustrating an example computer system for implementing one or more of the techniques described herein in accordance with at least one embodiment of the present disclosure.

The use of the same reference symbols in different drawings indicates similar or identical items.

### DETAILED DESCRIPTION OF THE DRAWINGS

The numerous innovative teachings of the present application will be described with particular reference to the presently preferred example embodiments. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

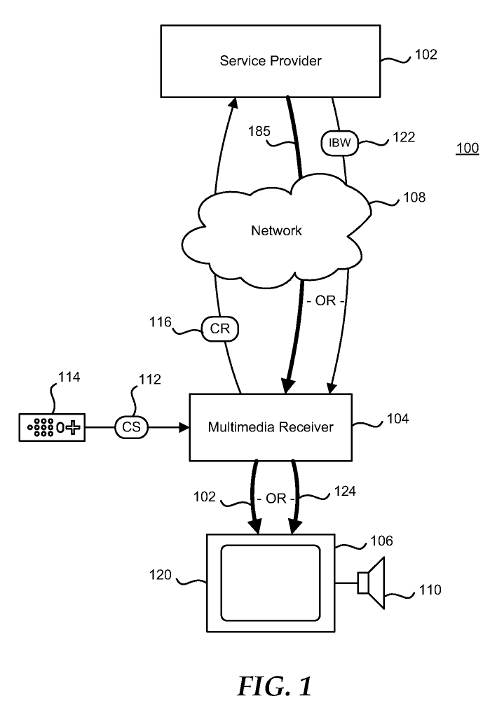

FIGS. 1-9 illustrate example techniques for notifying a viewer that a multimedia channel selected by the viewer is not able to be presented to the viewer due to insufficient bandwidth available in the network connection between the viewer's premises and a service provider. In at least one embodiment, the viewer selects a multimedia channel for presentation to the viewer. In response, the bandwidth requirements of the selected channel are compared with the available bandwidth of the network connection. In the event that the available bandwidth of the network connection meets, or is consistent with, the bandwidth requirements of the selected channel, the service provider initiates transmission of the data representative of the content of the selected channel to the viewer's premises. Otherwise, if the available bandwidth of the network connection does not meet, or is inconsistent with, the bandwidth requirements of the selected channel, the service provider transmits an insufficient bandwidth notification to the multimedia receiver located at the viewer's premises. In response to the insufficient bandwidth notification, the multimedia receiver provides an indicator to the viewer that the selected channel is not available for presentation due to insufficient bandwidth in the network connection. The indicator can include a visual indicator, such as text, a picture, or a symbol displayed on the viewer's display device. The indicator can include an audible indicator, such as a tone, tune, or a voiced notification. The indicator also can include a combination of a visual indicator and an audible indicator. Further, in one embodiment, a list of multimedia channels being provided to the viewer's premises is displayed for the viewer and the viewer is given the option to terminate provision of one or more of the other multimedia channels so as to make additional bandwidth available for the channel initially requested by the viewer.

The term “multimedia” refers to video content, audio content, or a combination thereof. Accordingly, the term “multimedia channel” refers to a stream of video content, a stream of audio content, or a combination thereof. The term “presentation” refers to the display of video content in a video context, the audible output of audio content in an audio context, or a combination thereof. Accordingly, the presentation of a multimedia channel includes one or both of a display of at least a portion of the stream of video content of the multimedia channel and the audible output of at least a portion of the stream of audio content of the multimedia channel. In the context of the output of audio content, either alone or in combination with the display of video content, a viewer is understood to be a listener.

In the context of a relatively fixed multimedia receiver, a viewer's premises can include, for example, a residence or place of work of the viewer, a car, a boat, a plane or other vehicle, and the like. In the context of a portable multimedia receiver, such as a multimedia-enabled cellular phone, a viewer's premises can include the viewer's personal space while operating the multimedia receiver.

For ease of illustration, certain techniques disclosed herein are described in an example context of an Internet Protocol Television (IPTV) network utilizing a set top box (STB) device to interface between a display device, such as a television or computer, and the multimedia content distribution network of a service provider. However, these techniques also can be implemented in other contexts without departing from the scope of the present disclosure.

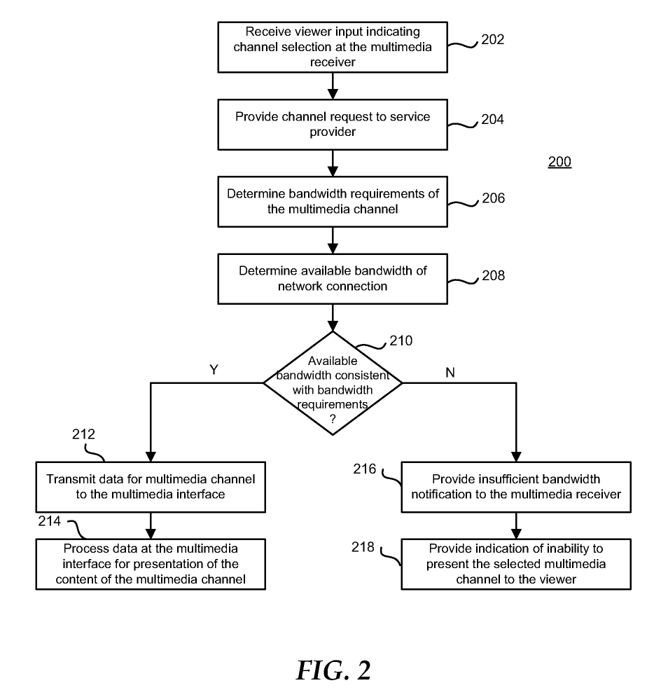

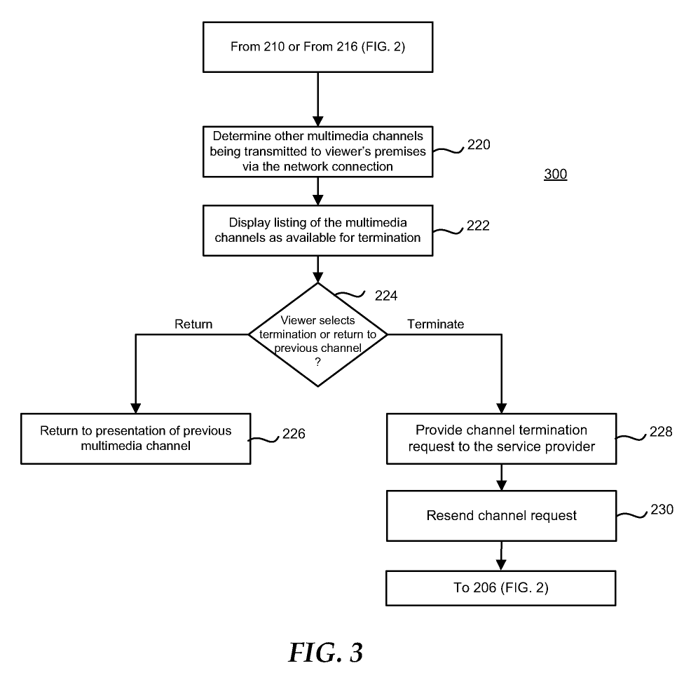

FIGS. 1-3 illustrate an example multimedia content distribution network 100 and example methods of its operation with respect to the provision of multimedia channels in accordance with at least one embodiment of the present disclosure. FIG. 1 illustrates the multimedia content distribution network 100, FIG. 2 illustrates an example method 200 for notifying a viewer of insufficient bandwidth for the provision of a selected multimedia channel, and FIG. 3 illustrates a method 300 that is an extension of the method 200 for providing the viewer with an option to terminate transmission of one or more other multimedia channels being provided to the viewer so as to free additional bandwidth for the provision of the selected channel.

In the depicted example of FIG. 1, the multimedia content distribution network 100 includes a service provider 102, a multimedia receiver 104, a display device 106, and a network 108, whereby the network 108 connects the multimedia receiver 104 and the service provider 102. In one embodiment, the multimedia receiver 104 and the display device 106 are located at a viewer's premises. The service provider 102 can include, for example, a cable television provider, a satellite television provider, an Internet-based multimedia content provider, and the like. The multimedia receiver 104 can include, for example, a set top box (STB) device, a digital network radio receiver, a portable multimedia device (e.g., a multimedia-enabled cellular phone or a digital radio receiver), and the like. The display device 106 can include, for example, a television or a monitor. The display device 106 can include, or be connected to, one or more speakers 110. The network 108 can include any of a variety of digital networks or a combination thereof. Examples of the network 108 can include an Internet-Protocol (IP)-based network, such as the Internet, an Ethernet network, a wireless network (e.g., an IEEE 802.11a/b/g/n-compatible network), a satellite network, a Bluetooth™ based network, and the like. The transmission medium of the network 108 for wire-based implementations can include, for example, a coaxial cable-based medium (e.g., a cable television medium), a digital subscriber line (DSL)-based medium (e.g., a plain old telephone system (POTS) medium), a fiber-optic medium, and the like.

In operation, a network connection is established between the service provider 102 and the multimedia receiver 104 over the network 108. The service provider 102 then streams data to the multimedia receiver 104 via the network connection, whereby the data represents content for one or more multimedia channels requested by the multimedia receiver 104. The data can include, for example, multimedia data encoded in accordance with the MPEG-2 standard or the MPEG-4 standard (also referred to as the H.264 standard). The multimedia receiver 104 processes the received data to generate display data and audio data and provides the display data and audio data for presentation to the viewer via the display device 106 and the speaker 110.

In at least one embodiment, the network connection between the service provider 102 and the multimedia receiver 104 has limited bandwidth available and therefore may be unable to satisfactorily transmit the data for a requested multimedia channel. To illustrate, the selected channel may be a high-definition (HD) channel, whereas the network connection may have a bandwidth sufficient only for standard-definition (SD) channels. As another example, the service provider 102 may already be transmitting one or more other multimedia channels via the network connection when the viewer selects a particular channel, and the transmission of these other channels may consume enough bandwidth to render the resulting available bandwidth of the network connection insufficient for transmitting the selected channel. Accordingly, in one embodiment, the viewer is provided with an indicator of the unavailability of the selected channel due to bandwidth limitations, thereby reducing the potential for viewer frustration arising from concern that one or more of the display device 106, the multimedia receiver 104, the service provider 102, or the network 108 is inoperable. FIGS. 2 and 3 illustrate example operations of the multimedia content distribution system 100 with respect to the provision of this indicator.

In the example method 200 of FIG. 2, the multimedia receiver 104 receives viewer input indicating selection of a multimedia channel for presentation at the display device 106 at block 202. The viewer input can include, for example, a channel select (CS) notification 112 received as a result of the viewer's manipulation of a remote control 114, a button panel (not shown), and the like. At block 204, the multimedia receiver 104 generates a channel request (CR) notification 116 and provides the CR notification 116 to the service provider 102 via, for example, the network 108. The CR notification 116 can include an identifier associated with the requested channel, such as a channel number, an identifier associated with the multimedia receiver 104 or other component at the viewer's premises (such as a residential gateway device), and the like.

At block 206, the service provider 102 receives the CR notification 116, and in response, determines the current bandwidth requirements of the multimedia channel identified in the CR notification 116. The bandwidth requirements of the multimedia channel can include, for example, one or more of a minimum peak bandwidth, a minimum sustained bandwidth, a quality-of-service (QoS) metric, and the like. Further, the bandwidth requirements of the multimedia channel can vary over time depending on, for example, the particular program being transmitted via the multimedia channel. The bandwidth requirements of the multimedia channel could have been previously determined and therefore the service provider 102 can access a database or other datastore to determine the bandwidth requirements. Alternately, the service provider 102 can analyze certain characteristics of the content of the current program of the multimedia channel to determine the bandwidth requirements. To illustrate, the service provider 102 may be able to identify which one of a plurality of bandwidth classes to apply to the current program of the requested multimedia channel based on an identification of a resolution of the current program, a frame rate of the current program, a content type of the current program (e.g., action, drama, nature, etc.), or a combination thereof.

At block 208, the service provider 102 determines the available bandwidth of the network connection between the service provider 102 and the viewer's premises using any of a variety of available bandwidth calculation techniques. In one embodiment, the available bandwidth can be determined by directly testing the network connection. Alternately, the available bandwidth can be calculated by subtracting from a known overall bandwidth of the network connection the expected bandwidth consumed by other multimedia channels being transmitted via the network connection.

At block 210, the service provider 102 determines whether the bandwidth requirements of the requested multimedia channel are consistent with the available bandwidth of the network connection by comparing the available bandwidth of the network connection with the bandwidth requirements of the requested multimedia channel. The bandwidth requirements of the requested multimedia channel can be said to be consistent with the available bandwidth when the data of the requested multimedia channel can be satisfactorily transmitted and processed in view of the available bandwidth of the network connection. Conversely, the bandwidth requirements of the requested multimedia channel can be said to be inconsistent with the available bandwidth when the data of the requested multimedia channel is at risk of being unsatisfactorily transmitted and processed in view of the available bandwidth. To illustrate, the available bandwidth may comprise a peak available bandwidth and a sustained available bandwidth. If the peak available bandwidth is greater than the peak bandwidth required for the requested multimedia channel but the sustained available bandwidth is considerably less than the sustained bandwidth required for the requested multimedia channel, it may be determined that the multimedia channel cannot be satisfactorily transmitted via the network connection due to, for example, the potential for buffer underflow. As another example, if alternately the sustained available bandwidth is sufficient for the sustained bandwidth required for the requested channel but the peak available bandwidth is slightly less than the peak bandwidth specified for the requested multimedia channel, it may be determined that the multimedia channel still can be satisfactorily transmitted with only limited visual artifacts due to the mismatch between peak bandwidth available and peak bandwidth required. The criteria for whether the available bandwidth and the bandwidth requirements are consistent or inconsistent can vary depending on the particular situation and therefore may be altered at the service provider 102 in view of certain circumstances.

In the event that the service provider 102 determines that the bandwidth requirements of the requested multimedia channel are consistent with the available bandwidth of the network connection, the service provider 102 begins transmitting a data stream 118 (e.g., a H.264-encoded data stream) representing the content of the requested multimedia channel to the multimedia receiver 104 at block 212. At block 214, the multimedia receiver 104 receives the data stream 118 and processes the data stream 118 for presentation of the content represented by the data stream 118 at the display device 106. The processing performed by the multimedia receiver 104 can include, for example, decoding the data stream to generate video data and audio data, converting the video data to display data 120 for transmission to the display device 106, converting the audio data to an analog signal for output to the speaker 110, and the like.

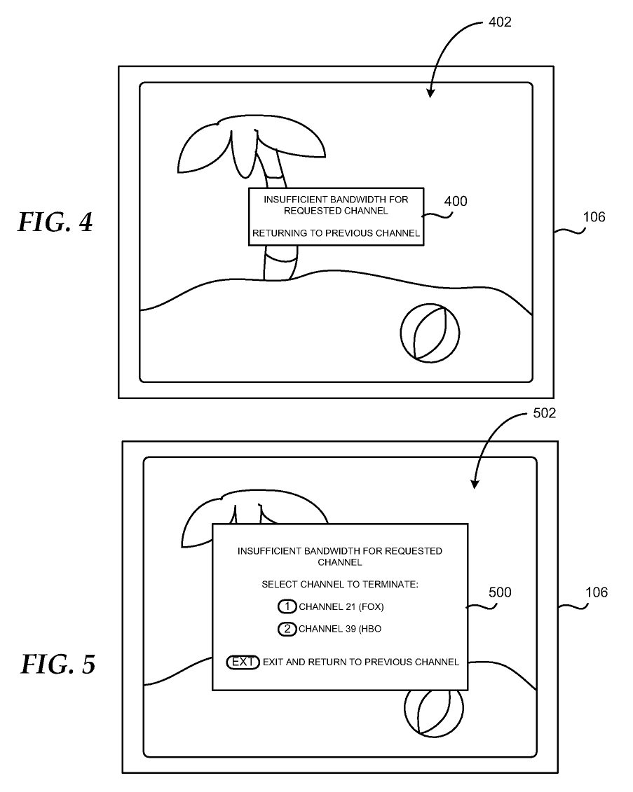

Otherwise, in the event that the that the service provider 102 determines that the bandwidth requirements of the requested multimedia channel are inconsistent with the available bandwidth of the network connection, the service provider 102 provides an insufficient bandwidth (IBW) notification 122 to the multimedia receiver 104 at block 216. The IBW notification 122 notifies the multimedia receiver 104 that the requested multimedia channel cannot be satisfactorily transmitted via the network connection under the current circumstances. Accordingly, in response to receiving the IBW notification 122, the multimedia receiver 104 provides to the viewer an indicator of the inability to present the requested channel due to insufficient bandwidth of the network connection. The indicator can include a visual indicator, an audible indicator, or a combination of the two. To illustrate, the multimedia receiver 104 can generate an on-screen display (OSD) 124 that overlays the content presently being displayed at the display device 106, whereby the content being displayed can include a blank frame or the content of the channel being displayed when the viewer initiated the channel change. The OSD 124 can include a pictorial representation to the viewer that the requested channel is unavailable, and further may identify the reason that the channel is unavailable, that is, due to insufficient bandwidth of the network connection. The pictorial representation can include text, symbols, pictures, or combinations thereof. In instances whereby the indicator includes an audible indicator, the audible indicator can be provided for output via the speaker 110 and can include a tone, a tune, a spoken notification, etc. An example of a visual indicator is described below with reference to FIG. 4.

Although method 200 is described in the context of an embodiment whereby the service provider 102 determines the available bandwidth of the network connection and the bandwidth requirements of the requested multimedia channel, one or both of these instead can be determined by the multimedia receiver 104. Likewise, the multimedia receiver 104 can perform the comparison described above with reference to block 210 to determine whether the requested multimedia channel can be transmitted, and if not, the multimedia receiver 104 can withhold provision of the CR notification 116 and provide for the viewer the indicator of the unavailability of the requested multimedia channel.

The method 300 depicted in FIG. 3 is an extension of the method 200 of FIG. 2 and continues from either block 210 or block 218 of method 200, depending on implementation. In response to determining at block 210 (FIG. 2) that the bandwidth requirements of the requested multimedia channel are inconsistent with the available bandwidth of the network connection, the service provider 102 identifies one or more other multimedia channels being transmitted to the viewer's premises via the network connection at block 220 and transmits data representative of the list of channels along with, or as part of, the IBW notification 122. Alternately, in response to receiving the IBW notification 122, the multimedia receiver 104 can identify those multimedia channels, if any, being transmitted to the multimedia receiver 104 or other device at the viewer's premises to generate the list of channels. The other multimedia channels can include, for example, a multimedia channel being recorded at the multimedia receiver 104, a multimedia channel being displayed in a picture-in-picture (PIP) mode at the display device 106, a multimedia channel being processed at another multimedia receiver at the viewer's premises, and the like.

At block 222, the multimedia receiver 104 displays the listing of multimedia channels and provides the viewer with the option to terminate the transmission of one or more of the listed channels via the network connection so as to increase the available bandwidth of the network connection. In one embodiment, the listing of channels is displayed with the OSD 124 in association with the visual indicator of insufficient bandwidth for provision of the requested channel. An example of the OSD 124 with a channel listing is described below with reference to FIG. 5.

As part of providing the viewer with the option to terminate provision of one or more of the other multimedia channels, the multimedia receiver 104 also can provide the viewer with the option to cancel the request for the multimedia channel. Accordingly, at block 224, the multimedia receiver receives viewer input indicating either to cancel the request for the multimedia channel or to terminate provision of one or more of the other multimedia channels. If the viewer opts to cancel the request for the multimedia channel, at block 226 the multimedia receiver 104 returns to presenting the previous multimedia channel that was being presented when the viewer provided the input indicating the selection of the new channel at block 202 of method 200.

Otherwise, if the viewer selects one of the other multimedia channels for termination, at block 228 the multimedia receiver 104 provides a channel termination request to the service provider 102. In response to receiving the channel termination request, the service provider 102 ceases transmission of the identified multimedia channel to the viewer's premises, thereby increasing the available bandwidth of the network connection. Accordingly, at block 230 the multimedia receiver 104 resends the CR notification 116 to the service provider 102 so as to request provision of the selected channel. The method 300 then returns to block 206 of FIG. 2 whereby the process of ascertaining whether there is sufficient bandwidth to transmit the requested multimedia channel can be repeated in view of the increased available bandwidth of the network connection.

FIG. 4 illustrates an example implementation of a visual indicator 400 for informing a viewer that a requested channel is unavailable due to insufficient bandwidth. In the illustrated example, the visual indicator 400 includes an on-screen display (OSD), such as the OSD 124 of FIG. 1, that overlays the display of content 402 from the channel being presented at the time the viewer requested the channel change. Alternately, the OSD can overlay a blank screen. The visual indicator 400 can include text, symbols, or pictures to convey to the viewer that the requested multimedia channel is unavailable, as well as to convey that insufficient bandwidth is the reason the requested multimedia channel is unavailable. The visual indicator 400 can be displayed for a predetermined amount of time (e.g., 10 seconds), at which point the visual indicator 400 is removed from display at the display device 106 and the multimedia receiver 104 returns to presenting content from the previous multimedia channel at the display device 106. Alternately, the multimedia receiver 104 can require viewer input (e.g., selection of a particular button on a remote control) before ceasing the display of the visual indicator 400.

FIG. 5 illustrates an example implementation of a visual indicator 500 so as to provide a viewer with an option to terminate provision of one or more other multimedia channels. As illustrated, the visual indicator 500 includes an OSD (e.g., OSD 124, FIG. 1) that overlays the display of content 502 from another channel being presented, or alternately overlays a blank screen. The visual indicator 500 can include a visual representation that the requested multimedia channel is unavailable due to insufficient bandwidth of the network connection. The visual indicator 500 also can include a list of multimedia channels available for termination and an indication that the viewer can select one or more of the listed multimedia channels (e.g., via selection of a corresponding button on a remote control) so as to terminate transmission of the selected multimedia channel via the network connection and therefore make additional bandwidth available for transmission of the requested multimedia channel. To facilitate the viewer in selecting a multimedia channel for termination, the visual indicator 500 can provide certain information regarding the listed multimedia channels to the viewer. To illustrate, the visual indicator 500 can identify whether a listed multimedia channel is being recorded at the multimedia receiver or other device at the viewer's premises, the visual indicator 500 can identify where the multimedia channel is being presented at the viewer's premises (e.g., at the viewer's display device, at another display device, etc.), a ranking of the multimedia channel, an indication of whether the program of the multimedia channel has previously been recorded, and the like. The visual indicator 500 also can include an exit or cancel option whereby the viewer can provide input (e.g., selection of a particular remote control button) indicating cancellation or withdrawal of the request for the multimedia channel, in response to which the multimedia receiver 104 can return to presenting the multimedia channel being presented when the viewer selected a change in channels.

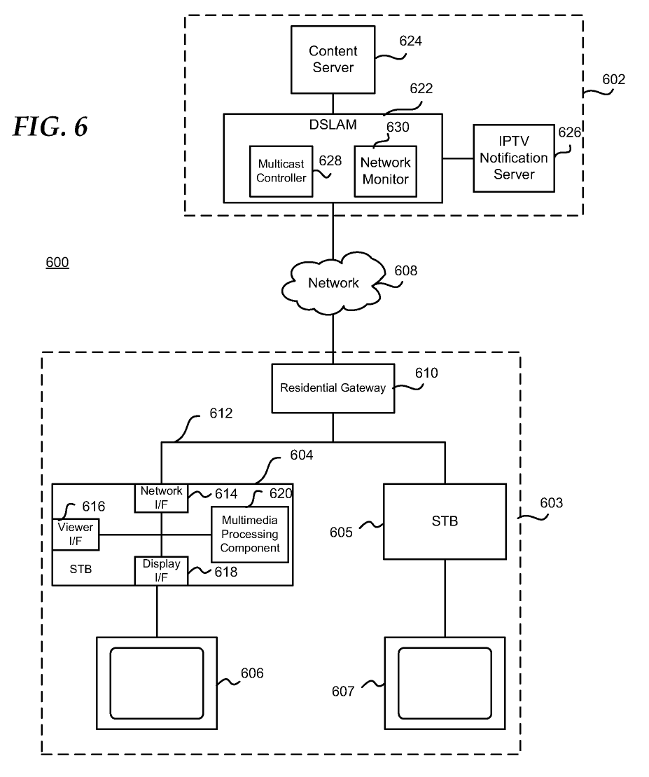

FIG. 6 illustrates a particular implementation of a multimedia content distribution system 600 in the context of a digital subscriber line (DSL) network in accordance with at least one embodiment of the present disclosure. In the depicted example, the multimedia content distribution system 600 (corresponding to the multimedia content distribution 100, FIG. 1) includes a service provider 602 (corresponding to service provider 102, FIG. 1) connected to a viewer's premises 603 via a network connection established at least in part via a DSL network 608 (e.g., a POTS network).

The viewer's premises 603 includes STB devices 604 and 605 (one embodiment of the multimedia receiver 104, FIG. 1), display devices 606 and 607, and a residential gateway 610. The residential gateway 610 is configured to interface between the DSL network 608 and an internal network 612 (e.g., a wireless network, an Ethernet network, a Universal Serial Bus (USB), and the like) at the viewer's premises 603. Accordingly, the residential gateway 610 can include a combined DSL modem and router. The STB device 604 includes a network interface 614, a viewer interface 616, a display interface 618, and a multimedia processing component 620. The STB device 605 may be similarly configured.

The network interface 614 includes any of a variety of network interfaces suitable for the internal network 612, such as wireless network interface, a wired Ethernet interface, a USB port, and the like. The viewer interface 616 includes an interface to receive viewer input, such as a remote control interface or a button panel. The display interface 618 includes any of a variety of interfaces to the display device 606, such as a digital video interface (DVI), a high-definition multimedia receiver (HDMI), an S-video interface, a composite video interface (e.g., a coaxial cable interface), a component video interface, and the like. The display interface 618 further can include an audio interface for providing audio signaling to the display device 606.

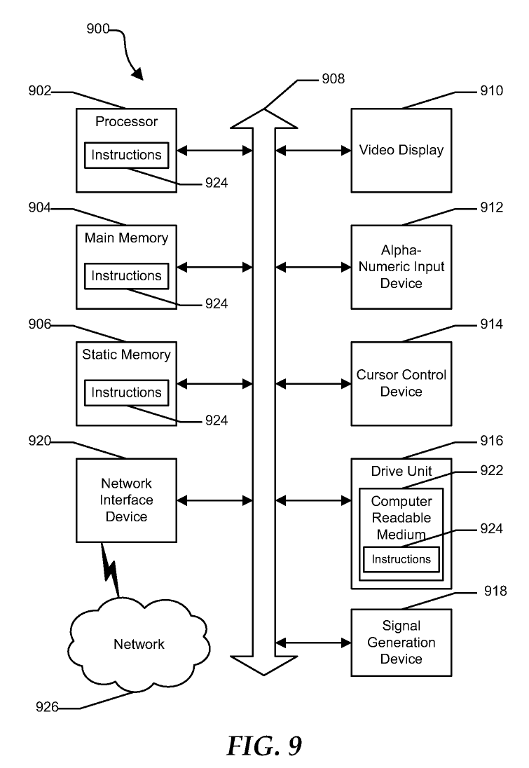

The multimedia processing component 620 is configured to control the network interface 614, the viewer interface 616, and the display interface 618. The multimedia processing component 620 further is configured to process incoming data streams for the presentation of the represented content at the display device 606. Additionally, the multimedia processing component 620 is configured to generate and provide channel request notifications and channel terminate notifications, process received insufficient bandwidth notifications, and provide visual indicators or audio indicators as described above. In one embodiment, the multimedia processing component 620 includes a storage element (e.g., a memory or a hard disk)(not shown) to store a program of instructions and a processor (not shown), whereby the program of instructions are executable by the processor to manipulate the processor so as to perform the techniques described herein with respect to a multimedia receiver. An example processor-based implementation of a STB device is described below with reference to FIG. 9.

The service provider 602 includes a DSL access multiplexer (DSLAM) 622, a content server 624, and an Internet Protocol Television (IPTV) notification server 626. The DSLAM 622 interfaces with the residential gateway 610 via the DSL network 608 and includes a multicast controller 628 and a network monitor 630. In one embodiment, the provision of multimedia channels to multiple viewers is handled by the DSLAM 622 via multicasting techniques, whereby the multicast controller 628 maintains a database of the multicast groups associated with corresponding multimedia channels and the addresses of devices at viewers' premises corresponding to each multicast group. The network monitor 630, in one embodiment, is configured to monitor the network connection between the DSLAM 622 and the residential gateway 610, including determining the available bandwidth of the network connection as described above, either on a periodic basis or in response to a request for provision of a multimedia channel to the viewer's premises 603.

The content server 624 includes one or more servers for providing the content of multimedia channels to viewers' premises as data streams representative of the multimedia channels. For a given multimedia channel, the content server 624 generates the corresponding data stream and provides the data stream to the DSLAM 622, which then multicasts the data stream to one or more viewers' premises via the DSL network 608 based on membership in the multicast address associated with the multimedia channel.

The IPTV notification server 626 is configured to provide various notifications to viewer's premises regarding operation and provision of services to the viewer. To illustrate, in addition to providing insufficient bandwidth notifications and channel list data as described below, the IPTV notification server 626 can provide information regarding incoming telephone calls (e.g., the caller ID and telephone number) that are communicated to the viewer's premises by the service provider 102 via the network connection.

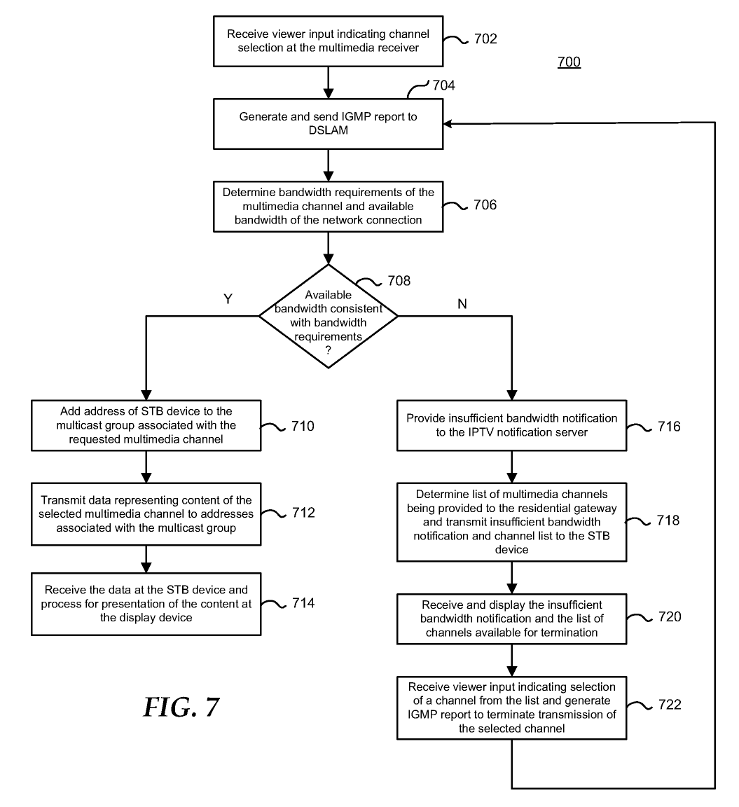

FIG. 7 illustrates an example method 700 for processing multimedia channel requests in the context of the multimedia content distribution system 600 of FIG. 6 in accordance with at least one embodiment of the present disclosure. At block 702 the STB device 604 receives viewer input indicating selection of a multimedia channel for provision at the viewer's premises 603. In response to the viewer input, at block 704 the multimedia processing component 604 generates an Internet Group Management Protocol (IGMP) report so as to request the addition of the address of the STB device 604 to the multicast group associated with requested multimedia channel (one example of the CR request 112, FIG. 1). The STB device 604 then provides the IGMP report to the DSLAM 622.

In response to receiving the IGMP report, the network monitor 630 provides an indicator of the available bandwidth of the network connection to the multicast controller 628. At block 706 the multicast controller 628 determines or accesses the bandwidth requirements of the requested channel and at block 708 the multicast controller 628 compares the bandwidth requirements with the available bandwidth to determine whether the available bandwidth and the bandwidth requirements are consistent.

If the available bandwidth and the bandwidth requirements are consistent, at block 710 the multicast controller 628 adds the address of the STB device 604 to the multicast group of the requested multimedia channel. Further, the DSLAM 630 can send a notification to the IPTV notification server 626 that the requested multimedia channel is to be provided to the viewer's premises 603, which is noted at the IPTV notification server 626 for channel list construction purposes. At block 712 the data stream representing the requested multimedia channel is multicast to the STB device 604 as a result of the addition of address of the STB device 604 to the multicast group associated with the requested multimedia channel. At block 714, the STB device 604 receives the data stream and processes the represented content for presentation at the display device 606.

Otherwise, if the available bandwidth and the bandwidth requirements are inconsistent, at block 716 the DSLAM 622 provides an insufficient bandwidth notification to the IPTV notification server 626. In response to the insufficient bandwidth notification, at block 718 the IPTV notification server 626 generates a list of multimedia channels being provided to the viewer's premises 603 and transmits an insufficient bandwidth notification to the STB device 604 via the DSLAM 622. Included with, or associated with, the insufficient bandwidth notification is data representing the list of multimedia channels. At block 720, the multimedia processing component 620 of the STB device 604 receives the insufficient bandwidth notification and data representing the list of multimedia channels and, in response, the multimedia processing component 620 presents an indicator that the requested multimedia channel to the viewer and also presents to the viewer an option to terminate provision of one or more of the listed multimedia channels. At block 722, the STB device 604 receives viewer input indicating selection of one of the listed channels, and in response, the multimedia processing component generates an IGMP report so as to request removal of the address of the STB device 604 from the multicast group associated with the channel selected from the list. Upon receipt of the IGMP report, the multicast controller 628 removes the address of the STB device 604 from the multicast group, thereby terminating the transmission of the selected channel to the STB device 604. Further, the DSLAM 622 sends a notification to the IPTV notification server 626 to remove the channel from the list maintained by the IPTV notification server 626 for the viewer's premises 603. The method 700 then can return to block 704 whereby the request for the channel is tried again in view of the increased available bandwidth of the network connection that resulted from termination of one or more of the multimedia channels being provided to the viewer's premises 603.

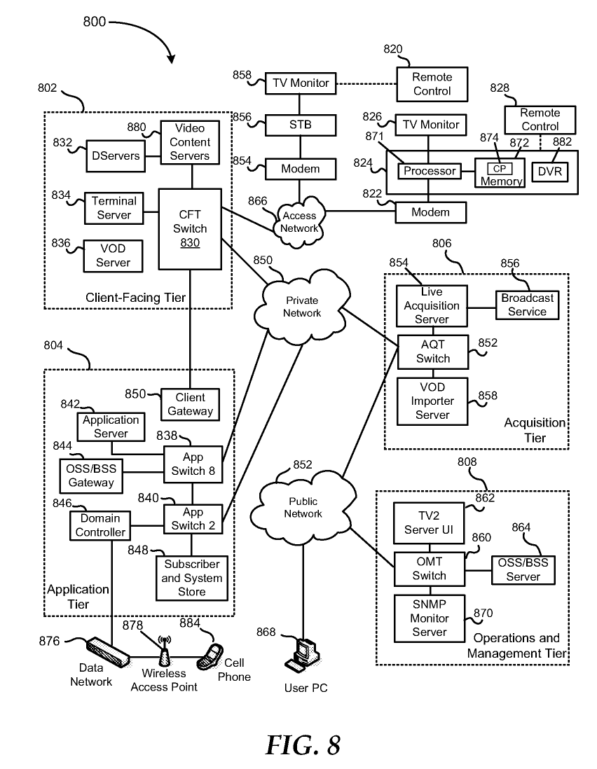

FIG. 8 illustrates an example Internet Protocol Television (IPTV) system 800 in which the disclosed video monitoring techniques can be implemented in accordance with at least one embodiment of the present disclosure. The IPTV system 800 can include a client facing tier 802, an application tier 804, an acquisition tier 806, and an operations and management tier 808. Each tier 802, 804, 806, and 808 is coupled to a private network 810, a public network 812, or both the private network 810 and the public network 812. For example, the client-facing tier 802 can be coupled to the private network 810. Further, the application tier 804 can be coupled to the private network 810 and to the public network 812, such as the Internet. The acquisition tier 806 can also be coupled to the private network 810 and to the public network 812. Moreover, the operations and management tier 808 can be coupled to the public network 812.

The various tiers 802, 804, 806, and 808 communicate with each other via the private network 810 and the public network 812. For instance, the client-facing tier 802 can communicate with the application tier 804 and the acquisition tier 806 via the private network 810. The application tier 804 can also communicate with the acquisition tier 806 via the private network 810. Further, the application tier 804 can communicate with the acquisition tier 806 and the operations and management tier 808 via the public network 812. Moreover, the acquisition tier 806 can communicate with the operations and management tier 808 via the public network 812. In a particular embodiment, elements of the application tier 804 can communicate directly with the client-facing tier 802.

The client-facing tier 802 can communicate with user equipment via a private access network 866, such as an Internet Protocol Television (IPTV) network. In an illustrative embodiment, modems, such as a first modem 814 and a second modem 822 can be coupled to the private access network 866. The client-facing tier 802 can communicate with a first representative STB device 816 via the first modem 814 and with a second representative STB device 824 via the second modem 822. The client-facing tier 802 can communicate with a large number of set-top boxes, such as the representative set-top boxes 816 and 824, over a wide geographic area, such as a regional area, a metropolitan area, a viewing area, or any other suitable geographic area that can be supported by networking the client-facing tier 802 to numerous set-top box devices. In an illustrative embodiment, the client facing tier or any portion thereof can be included at a video head-end office.

In one embodiment, the client-facing tier 802 can be coupled to the modems 814 and 822 via fiber optic cables. Alternatively, the modems 814 and 822 can be digital subscriber line (DSL) modems that are coupled to one or more network nodes via twisted pairs, and the client-facing tier 802 can be coupled to the network nodes via fiber-optic cables. Each set-top box device 816 and 824 can process data received through the private access network 866 via an IPTV software platform such as Microsoft® TV IPTV Edition.

Additionally, the first set-top box device 816 can be coupled to a first display device 818, such as a first television monitor, and the second set-top box device 824 can be coupled to a second display device 826, such as a second television monitor. Moreover, the first set-top box device 816 can communicate with a first remote control 820, and the second set-top box device can communicate with a second remote control 828. In an exemplary, non-limiting embodiment, each set-top box device 816 and 824 can receive data or video from the client-facing tier 802 via the private access network 866 and render or display the data or video at the display devices 818 and 826 to which it is coupled. In an illustrative embodiment, the set-top box devices 816 and 824 can include tuners that receive and decode television programming information for transmission to the display devices 818 and 826. The television tuner can be National Television System Committee (NTSC) tuner, an Advanced Television System Committee (ATSC), another suitable analog or digital tuner, or any combination thereof. A signal for a television channel can pass through the tuner before the content is displayed on a monitor.

In an exemplary, non-limiting embodiment, STB devices 816 and 824 can receive a data stream including video content data and audio content data from the client-facing tier 802 via the private access network 866. The STB device 816 and 824 can transmit the video content to an external display device, such as the television monitors 818 and 826. The STB devices 816 and 824 can also communicate commands received from the remote control devices 820 and 828 to the client-facing tier 802 via the private access network 866. The STB devices 816 and 824, in one embodiment, implement one or more of the display formatting techniques described above with reference to FIGS. 1-4.

In an illustrative embodiment, the client-facing tier 802 can include a client-facing tier (CFT) switch 830 that manages communication between the client-facing tier 802 and the private access network 866 and between the client-facing tier 802 and the private network 810. As shown, the CFT switch 830 is coupled to one or more data servers 832 that store data transmitted in response to viewer requests, such as video-on-demand material. The CFT switch 830 can also be coupled to a terminal server 834 that provides terminal devices, such as a game application server 868 and other devices with a common connection point to the private network 810. In a particular embodiment, the CFT switch 830 can also be coupled to a video-on-demand (VOD) server 836 that stores or provides VOD content imported by the IPTV system 800. The client-facing tier 802 can also include one or more channel provision servers 880 that transmit video content requested by viewers via their STB devices 816 and 824. In an illustrative, non-limiting embodiment, the channel provision servers 880 can include one or more multicast servers.

As shown in FIG. 8, the application tier 804 can communicate with both the private network 810 and the public network 812. In this embodiment, the application tier 804 can include a first application tier (APP) switch 838 and a second APP switch 840. In a particular embodiment, the first APP switch 838 can be coupled to the second APP switch 840. The first APP switch 838 can be coupled to an application server 842 and to an OSS/BSS gateway 844. The application server 842 provides applications to the set-top box devices 816 and 824 via the private access network 866, so the set-top box devices 816 and 824 can provide functions, such as display, messaging, processing of IPTV data and VOD material, etc. In a particular embodiment, the OSS/BSS gateway 844 includes operation systems and support (OSS) data, as well as billing systems and support (BSS) data.

Further, the second APP switch 840 can be coupled to a domain controller 846 that provides web access, for example, to users via the public network 812. The second APP switch 840 can be coupled to a subscriber and system store 848 that includes account information, such as account information that is associated with users who access the system 800 via the private network 810 or the public network 812. In a particular embodiment, the application tier 804 can also include a client gateway 850 that communicates data directly to the client-facing tier 802. In this embodiment, the client gateway 850 can be coupled directly to the CFT switch 830. The client gateway 850 can provide user access to the private network 810 and the tiers coupled thereto.

In a particular embodiment, the set-top box devices 816 and 824 can access the system via the private access network 866, using information received from the client gateway 850. The private access network 866 provides security for the private network 810. User devices can access the client gateway 850 via the private access network 866, and the client gateway 850 can allow such devices to access the private network 810 once the devices are authenticated or verified. Similarly, the client gateway 850 can prevent unauthorized devices, such as hacker computers or stolen set-top box devices from accessing the private network 810, by denying access to these devices beyond the private access network 866.

For example, when a set-top box device 816 accesses the system 800 via the private access network 866, the client gateway 850 can verify subscriber information by communicating with the subscriber and system store 848 via the private network 810, the first APP switch 838 and the second APP switch 840. Further, the client gateway 850 can verify billing information and status by communicating with the OSS/BSS gateway 844 via the private network 810 and the first APP switch 838. The OSS/BSS gateway 844 can transmit a query across the first APP switch 838 to the second APP switch 840, and the second APP switch 840 can communicate the query across the public network 812 to an OSS/BSS server 864. After the client gateway 850 confirms subscriber and/or billing information, the client gateway 850 can allow the set-top box device 816 access to IPTV content and VOD content. If the client gateway 850 cannot verify subscriber information for the set-top box device 816, for example because it is connected to a different twisted pair, the client gateway 850 can deny transmissions to and from the set-top box device 816 beyond the private access network 866.

The acquisition tier 806 includes an acquisition tier (AQT) switch 852 that communicates with the private network 810. The AQT switch 852 can also communicate with the operations and management tier 808 via the public network 812. In a particular embodiment during operation of the IPTV system, the live acquisition server 854 can acquire television or movie content. The live acquisition server 854 can transmit the television or movie content to the AQT switch 852, and the AQT switch can transmit the television or movie content to the CFT switch 830 via the private network 810.

Further, the television or movie content can be transmitted to the channel provision servers 880, where it can be encoded, formatted, stored, or otherwise manipulated and prepared for communication to the STB devices 816 and 824. The CFT switch 830 can communicate the television or movie content to the modems 814 and 822 via the private access network 866. The STB devices 816 and 824 can receive the television or movie content via the modems 814 and 822, and can transmit the television or movie content to the television monitors 818 and 826. In an illustrative embodiment, video or audio portions of the television or movie content can be streamed to the STB devices 816 and 824.

Further, the AQT switch can be coupled to a VOD importer server 858 that stores television or movie content received at the acquisition tier 806 and communicates the stored content to the VOD server 836 at the client-facing tier 802 via the private network 810. Additionally, at the acquisition tier 806, the VOD importer server 858 can receive content from one or more VOD sources outside the IPTV system 800, such as movie studios and programmers of non-live content. The VOD importer server 858 can transmit the VOD content to the AQT switch 852, and the AQT switch 852, in turn, can communicate the material to the CFT switch 830 via the private network 810. The VOD content can be stored at one or more servers, such as the VOD server 836.

When users issue requests for VOD content via the STB devices 816 and 824, the requests can be transmitted over the private access network 866 to the VOD server 836 via the CFT switch 830. Upon receiving such requests, the VOD server 836 can retrieve the requested VOD content and transmit the content to the STB devices 816 and 824 across the private access network 866 via the CFT switch 830. The STB devices 816 and 824 can transmit the VOD content to the television monitors 818 and 826. In an illustrative embodiment, video or audio portions of VOD content can be streamed to the STB devices 816 and 824.

The operations and management tier 808 can include an operations and management tier (OMT) switch 860 that conducts communication between the operations and management tier 808 and the public network 812. In the embodiment illustrated by FIG. 8, the OMT switch 860 is coupled to a TV2 server 862. Additionally, the OMT switch 860 can be coupled to the OSS/BSS server 864 and to a simple network management protocol (SNMP) monitor 870 that monitors network devices within or coupled to the IPTV system 800. In a particular embodiment, the OMT switch 860 can communicate with the AQT switch 852 via the public network 812.

In a particular embodiment during operation of the IPTV system, the live acquisition server 854 can acquire television content from the broadcast service 856. The live acquisition server 854 can transmit the television or movie content to the AQT switch 852, and the AQT switch 852 in turn can transmit the television content to the CFT switch 830 via the private network 810 or to the OMT switch 860 via the public network 812. Further, the television content can be encoded at the D-servers 832, and the CFT switch 830 can communicate the television content to the modems 814 and, 822 via the private access network 866. The set-top box devices 816 and 824 can receive the television content from the modems 814 and 822, decode the television content, and transmit the content to the display devices 818 and 826 according to commands from the remote control devices 820 and 828.

Additionally, at the acquisition tier 806, the video-on-demand (VOD) importer server 858 can receive content from one or more VOD sources outside the IPTV system 800, such as movie studios and programmers of non-live content. The VOD importer server 858 can transmit the VOD content to the AQT switch 852, and the AQT switch 852 in turn can communicate the material to the CFT switch 830 via the private network 810. The VOD content can be stored at one or more servers, such as the VOD server 836.

When a user issues a request for VOD content to set-top box devices 816 and 824, the request can be transmitted over the private access network 866 to the VOD server 836 via the CFT switch 830. Upon receiving such a request, the VOD server 836 can retrieve requested VOD content and transmit the content to the set-top box devices 816 and 824 across the private access network 866 via the CFT switch 830. In an illustrative embodiment, the live acquisition server 854 can transmit the television content to the AQT switch 852, and the AQT switch 852 in turn can transmit the television content to the OMT switch 860 via the public network 812. In this embodiment, the OMT switch 860 can transmit the television content to the TV2 server 862 for display to users accessing the user interface at the TV2 server. For example, a user can access the TV2 server 862 using a personal computer 868 coupled to the public network 812.

The domain controller 846 communicates with the public network 812 via the second APP switch 840. Additionally, the domain controller 846 can communicate via the public network 812 with the personal computer 868. For example, the domain controller 846 can display a web portal via the public network 812 and allow users to access the web portal using the PC 868. Further, in an illustrative embodiment, the domain controller 846 can communicate with at least one wireless network access point 878 over a data network 876. In this embodiment, each wireless network access device 878 can communicate with user wireless devices, such as a cellular telephone 884.

In a particular embodiment, a set-top box device such as the second set-top box device 824 can include an STB processor 871 and an STB memory device 872 that is accessible to the STB processor 871. The set-top box device 824 also includes a STB computer program 874 that is embedded within the STB memory device 872. In a particular embodiment, the STB computer program 874 can contain instructions to receive and execute at least one user television viewing preference that a user has entered by accessing an Internet user account via the domain controller 846. For example, the user can use the PC 868 to access a web portal maintained by the domain controller 846 via the Internet. The domain controller 846 can query the subscriber and system store 848 via the private network 810 for account information associated with the user. In a particular embodiment, the account information can associate the user's Internet account with the second set-top box device 824. For instance, in an illustrative embodiment, the account information can relate the user's account to the second set-top box device 824, by associating the user account with an IP address of the second set-top box device with data relating to one or more twisted pairs connected with the second set-top box device 824, with data related to one or more fiber optic cables connected with the second set-top box device 824, with an alphanumeric identifier of the second set-top box device 824, with any other data that is suitable for associating second set-top box device 824 with a user account, or with any combination of these.

The STB computer program 874 can contain instructions to receive many types of user preferences from the domain controller 846 via the access network 866. For example, the STB computer program 874 can include instructions to receive a request to record at least one television program at a video content storage module such as a digital video recorder (DVR) 882 within the second set-top box device 824. In this example embodiment, the STB computer program 874 can include instructions to transmit the request to the DVR 882, where the television program(s) are recorded. In an illustrative embodiment, the STB computer program 874 can include instructions to receive from the DVR 882 a recording status with respect to one or more of the television programs and to transmit at least one message regarding the status to a wireless device, such as the cellular telephone 884. The message can be received at the CFT switch 830, for instance, and communicated to the domain controller 846 across the private network 810 via the second APP switch 840. Further, the domain controller 846 can transmit the message to the wireless data network 876, directly or via the public network 812, and on to the wireless network access point 878. The message can then be transmitted to the cellular telephone 884. In an illustrative embodiment, the status can be sent via a wireless access protocol (WAP).

FIG. 9 shows an illustrative embodiment of a general computer system 900 in accordance with at least one embodiment of the present disclosure. The computer system 900 can include a set of instructions that can be executed to cause the computer system 900 to perform any one or more of the methods or computer based functions disclosed herein. The computer system 900 may operate as a standalone device or may be connected, e.g., using a network, to other computer systems or peripheral devices.

In a networked deployment, the computer system may operate in the capacity of a server or as a client user computer in a server-client user network environment, or as a peer computer system in a peer-to-peer (or distributed) network environment. The computer system 900 can also be implemented as or incorporated into, for example, a STB device. In a particular embodiment, the computer system 900 can be implemented using electronic devices that provide voice, video or data communication. Further, while a single computer system 900 is illustrated, the term “system” shall also be taken to include any collection of systems or sub-systems that individually or jointly execute a set, or multiple sets, of instructions to perform one or more computer functions.

The computer system 900 may include a processor 902, e.g., a central processing unit (CPU), a graphics processing unit (GPU), or both. Moreover, the computer system 900 can include a main memory 904 and a static memory 906 that can communicate with each other via a bus 908. As shown, the computer system 900 may further include a video display unit 910, such as a liquid crystal display (LCD), an organic light emitting diode (OLED), a flat panel display, a solid state display, or a cathode ray tube (CRT). Additionally, the computer system 900 may include an input device 912, such as a keyboard, and a cursor control device 914, such as a mouse. The computer system 900 can also include a disk drive unit 916, a signal generation device 918, such as a speaker or remote control, and a network interface device 920.

In a particular embodiment, as depicted in FIG. 9, the disk drive unit 916 may include a computer-readable medium 922 in which one or more sets of instructions 924, e.g. software, can be embedded. Further, the instructions 924 may embody one or more of the methods or logic as described herein. In a particular embodiment, the instructions 924 may reside completely, or at least partially, within the main memory 904, the static memory 906, and/or within the processor 902 during execution by the computer system 900. The main memory 904 and the processor 902 also may include computer-readable media. The network interface device 920 can provide connectivity to a network 926, e.g., a wide area network (WAN), a local area network (LAN), or other network.

In an alternative embodiment, dedicated hardware implementations such as application specific integrated circuits, programmable logic arrays and other hardware devices can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

The present disclosure contemplates a computer-readable medium that includes instructions 924 or receives and executes instructions 924 responsive to a propagated signal, so that a device connected to a network 926 can communicate voice, video or data over the network 926. Further, the instructions 924 may be transmitted or received over the network 926 via the network interface device 920.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writeable memory. Additionally, the computer-readable medium can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although the present specification describes components and functions that may be implemented in particular embodiments with reference to particular standards and protocols, the invention is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

What is claimed is:

1. A method comprising:
determining an available bandwidth of a network connection between a service provider and a multimedia receiver in response to a request for a first multimedia channel by the multimedia receiver;
determining a bandwidth requirement of the first multimedia channel; and
in response to determining the bandwidth requirement is inconsistent with the available bandwidth, providing to a viewer an indicator that the first multimedia channel is unavailable for presentation by the multimedia receiver.

2. The method of claim 1, further comprising:
in response to determining the bandwidth requirement is consistent with the available bandwidth:
transmitting data representative of content of the first multimedia channel from the service provider to the multimedia receiver via the network connection; and
processing the data at the multimedia receiver for presentation of the content of the first multimedia channel.

3. The method of claim 1, wherein determining the available bandwidth of the network connection comprises determining the available bandwidth of the network connection at the service provider.

4. The method of claim 3, further comprising:
in response to determining the bandwidth requirement is inconsistent with the available bandwidth, providing an insufficient bandwidth notification from the service provider to the multimedia receiver; and
wherein providing the indicator to the viewer comprises providing the indicator to the viewer in response to receiving the insufficient bandwidth notification at the multimedia receiver.

5. The method of claim 1, further comprising:
receiving, at the multimedia receiver, viewer input indicating selection of the first multimedia channel for presentation;
providing the request for the first multimedia channel from the multimedia receiver to the service provider in response to receiving the viewer input; and
wherein determining the available bandwidth and determining the bandwidth requirement comprise determining the available bandwidth and determining the bandwidth requirement at the service provider in response to receiving the request for the first multimedia channel.

6. The method of claim 1, further comprising:
in response to determining the bandwidth requirement is inconsistent with the available bandwidth:
identifying one or more multimedia channels being transmitted to the multimedia receiver via the network connection; and
providing to the viewer an option to terminate transmission of at least one multimedia channel of the one or more multimedia channels.

7. The method of claim 6, further comprising:
in response to the viewer opting to terminate transmission of a second multimedia channel of the one or more multimedia channels:
terminating transmission of the second multimedia channel from the service provider to the multimedia receiver;
determining the available bandwidth of the network connection in response to terminating transmission of the second multimedia channel; and
in response to determining the bandwidth requirement is consistent with the available bandwidth, transmitting data representative of the first multimedia channel from the service provider to the multimedia receiver via the network connection.

8. The method of claim 6, wherein providing an option to terminate transmission of at least one multimedia channel comprises:
displaying a listing of the one or more multimedia channels being transmitted to the multimedia receiver via the network connection;
configuring the multimedia receiver to receive viewer input indicating a selection of one of the multimedia channels of the listing; and
providing, from the multimedia receiver to the service provider, a request to terminate transmission of a multimedia channel identified by the viewer input.

9. The method of claim 1, wherein the indicator comprises at least one of a visual indicator or an audible indicator.

10. The method of claim 1, wherein the multimedia receiver is located at the viewer's premises.

11. The method of claim 1, wherein the indicator that the first multimedia channel is unavailable for presentation by the multimedia receiver includes an indicator to the viewer that the first multimedia channel is unavailable due to insufficient bandwidth.

12. A method comprising:
receiving viewer input indicating selection of a first multimedia channel at a multimedia receiver coupled to a service provider via a network connection;
transmitting a request for the first multimedia channel from the multimedia receiver to the service provider;
receiving, at the multimedia receiver, an insufficient bandwidth notification from the service provider that an available bandwidth of a network connection between the service provider and the multimedia receiver is insufficient for transmission of data representative of the first multimedia channel; and
providing, via the multimedia receiver, an indicator to the viewer that the first multimedia channel is unavailable for presentation in response to receiving the insufficient bandwidth notification.

13. The method of claim 12, further comprising:
providing, to the viewer in response to receiving the insufficient bandwidth notification, a listing of multimedia channels being transmitted via the network connection;
receiving, at the multimedia receiver, viewer input indicating selection of a second multimedia channel from the listing of multimedia channels; and
providing a request to terminate transmission of the second multimedia channel from the multimedia receiver to the service provider.

14. The method of claim 12, wherein providing the indicator to the viewer comprises providing a visual indicator for display at a display device associated with the multimedia receiver.

15. The method of claim 12, wherein providing the indicator to the viewer comprises providing an audible indicator for output at a display device associated with the multimedia receiver.

16. A multimedia receiver comprising:
a network interface configured for a network connection with a service provider;
a display interface coupleable to a display device;
a viewer input interface; and
a multimedia processing component configured to:
provide a request for a first multimedia channel to the network interface for transmission to the service provider in response to receiving viewer input indicating selection of the first multimedia channel;
receive a notification from the service provider that an available bandwidth of the network connection is insufficient for transmission of data representative of the first multimedia channel; and
provide to the viewer via the display device an indicator that the multimedia receiver is unable to provide the first multimedia channel in response to receiving the notification.

17. The multimedia receiver of claim 16, wherein the multimedia processing component further is to:
provide, to the viewer in response to receiving the notification, a listing of multimedia channels being transmitted via the network connection;
receive viewer input indicating selection of a second multimedia channel from the listing of multimedia channels; and
provide a request to terminate transmission of the second multimedia channel from the multimedia receiver to the service provider.

18. The multimedia receiver of claim 16, wherein the indicator is a visual indicator and the multimedia processing component is configured to provide the visual indicator to the display device via the display interface.

19. The multimedia receiver of claim 16, wherein the indicator is an audible indicator and the multimedia processing component is configured to provide the audible indicator to the display device via the display interface.

20. The multimedia receiver of claim 16, wherein the multimedia receiver comprises a set top box (STB) device.

21. A computer readable medium embodying a computer program, the computer program comprising:
instructions configured to manipulate a processor of a multimedia receiver to provide a request for a first multimedia channel to a service provider in response to receiving viewer input indicating selection of the first multimedia channel;
instructions configured to manipulate the processor of the multimedia receiver to receive a notification from the service provider that an available bandwidth of the network connection is insufficient for transmission of data representative of the first multimedia channel; and
instructions configured to manipulate the processor of the multimedia receiver to provide to the viewer an indicator that the multimedia receiver is unable to provide the first multimedia channel in response to receiving the notification.

22. The computer readable medium of claim 21, wherein the computer program further comprises:
instructions configured to manipulate the processor of the multimedia receiver to provide, to the viewer in response to receiving the notification, a listing of multimedia channels being transmitted via the network connection;
instructions configured to manipulate the processor of the multimedia receiver to receive viewer input indicating selection of a second multimedia channel from the listing of multimedia channels; and
instructions configured to manipulate the processor of the multimedia receiver to provide a request to terminate transmission of the second multimedia channel from the multimedia receiver to the service provider.

23. The computer readable medium of claim 21, wherein the indicator is a visual indicator and the multimedia processing component is configured to provide the visual indicator to the display device via the display interface.

24. The computer readable medium of claim 21, wherein the indicator is an audible indicator and the multimedia processing component is configured to provide the audible indicator to the display device via the display interface.
